(19) United States
(12) Patent Application Publication
(10) Pub. No.: US 2025/0275243 A1
(43) Pub. Date: Aug. 28, 2025

(54) BACKSIDE VIA FOR BACKSIDE POWER SCHEME

(71) Applicant: INTERNATIONAL BUSINESS MACHINES CORPORATION, ARMONK, NY (US)

(72) Inventors: Min Gyu Sung, Latham, NY (US); Tao Li, Slingerlands, NY (US); Ruilong Xie, Niskayuna, NY (US); Lijuan Zou, Albany, NY (US)

(21) Appl. No.: 18/584,130

(22) Filed: Feb. 22, 2024

(51) Int. Cl. H01L 27/12

(52) U.S. Cl. CPC H10D 86/60; H10D 86/0214; H10D 86/441

(57) ABSTRACT

According to the embodiment of the present invention, a semiconductor device includes a first nanodevice including a plurality of first transistors and a second nanodevice including a plurality of second transistors. The first nanodevice includes a first source/drain contact having a first bulge towards a backside of the first source/drain contact. The second nanodevice is located adjacent to and parallel to the first nanodevice along an x-axis. The first bulge is located between the first nanodevice and the second nanodevice. A backside via extends downwards from a backside of the first nanodevice and the second nanodevice to connect to a backside of the first bulge.

### BACKGROUND

The present invention relates generally to the field of microelectronics, and more particularly to a semiconductor device structure, and a method for forming a semiconductor device.

A nanosheet (NS) is the lead device architecture in continuing CMOS scaling. However, nanosheet technology has shown issues when scaling down such that as the devices become smaller and closer together, they are interfering with each other. Furthermore, as the devices become smaller and closer together, forming the connections to a backside power network is becoming more difficult.

### SUMMARY

According to the embodiment of the present invention, a semiconductor device includes a first nanodevice including a plurality of first transistors and a second nanodevice including a plurality of second transistors. The first nanodevice includes a first source/drain contact having a first bulge towards a backside of the first source/drain contact. The second nanodevice is located adjacent to and parallel to the first nanodevice along an x-axis. The first bulge is located between the first nanodevice and the second nanodevice. A backside via extends downwards from a backside of the first nanodevice and the second nanodevice to connect to a backside of the first bulge.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a top-down view of a plurality of nanodevices, in accordance with the embodiment of the present invention.

FIGS. 2-3 illustrate cross sections Y₁, and Y₂, respectively, of the plurality of nanodevices after interlayer dielectric (ILD) deposition, nanosheet formation, shallow trench isolation (STI) region formation, gate formation, source/drain formation, etch stop layer formation, underlying substrate liner formation, and CMP, in accordance with the embodiment of the present invention.

FIG. 4 illustrates a top-down view of the plurality of nanodevices after the formation of a plurality of gate contacts, in accordance with the embodiment of the present invention.

FIGS. 5-6 illustrate cross sections Y₁, and Y₂, respectively, of the plurality of nanodevices after the formation of the plurality of gate contacts, in accordance with the embodiment of the present invention.

FIGS. 7-8 illustrate cross sections Y₁, and Y₂, respectively, of the plurality of nanodevices after the formation of a lithography mask layer, a first trench, and a second trench, in accordance with the embodiment of the present invention.

FIGS. 9-10 illustrate cross sections Y₁, and Y₂, respectively, of the plurality of nanodevices after the formation of a plurality of first frontside dielectric liners, in accordance with the embodiment of the present invention.

FIGS. 11-12 illustrate cross sections Y₁, and Y₂, respectively, of the plurality of nanodevices after the formation of a plurality of second frontside dielectric liners, in accordance with the embodiment of the present invention.

FIGS. 13-14 illustrate cross sections Y₁, and Y₂, respectively, of the plurality of nanodevices after the formation of a third trench and a fourth trench, in accordance with the embodiment of the present invention.

FIG. 15 illustrates a top-down view of the plurality of nanodevices after the formation of a plurality of source/drain contacts, in accordance with the embodiment of the present invention.

FIGS. 16-17 illustrate cross sections Y₁, and Y₂, respectively, of the plurality of nanodevices after the formation of the plurality of source/drain contacts, in accordance with the embodiment of the present invention.

FIGS. 18-19 illustrate cross sections Y₁, and Y₂, respectively, of the plurality of nanodevices after the formation of a back-end-of-line (BEOL) layer, a bonding oxide layer, and bonding to a carrier wafer, in accordance with the embodiment of the present invention.

FIGS. 20-21 illustrate cross sections Y₁, and Y₂, respectively, of the plurality of nanodevices after the carrier wafer is flipped and the substrate is removed, in accordance with the embodiment of the present invention.

FIGS. 22-23 illustrate cross sections Y₁, and Y₂, respectively, of the plurality of nanodevices after the removal of the etch stop layer and the selective recessing of the underlying substrate layer, in accordance with the embodiment of the present invention.

FIGS. 24-25 illustrate cross sections Y₁, and Y₂, respectively, of the plurality of nanodevices after the formation of a fifth trench, a sixth trench, and a seventh trench, in accordance with the embodiment of the present invention.

FIG. 26 illustrates a top-down view of the plurality of nanodevices after the formation of a plurality of backside dielectric liners and a plurality of dielectric caps, in accordance with the embodiment of the present invention.

FIGS. 27-28 illustrate cross sections Y₁, and Y₂, respectively, of the plurality of nanodevices after the formation of the plurality of backside dielectric liners and the plurality of dielectric caps, in accordance with the embodiment of the present invention.

FIG. 29 illustrates a top-down view of the plurality of nanodevices after the formation of a dielectric fill, in accordance with the embodiment of the present invention.

FIGS. 30-31 illustrate cross sections Y₁, and Y₂, respectively, of the plurality of nanodevices after the formation of the dielectric fill, in accordance with the embodiment of the present invention.

FIGS. 32-33 illustrate cross sections Y₁, and Y₂, respectively, of the plurality of nanodevices after the formation of a second lithography mask layer and an eighth trench, in accordance with the embodiment of the present invention.

FIG. 34 illustrates a top-down view of the plurality of nanodevices after the formation of a backside via, in accordance with the embodiment of the present invention.

FIGS. 35-36 illustrate cross sections Y₁, and Y₂, respectively, of the plurality of nanodevices after the formation of the backside via, in accordance with the embodiment of the present invention.

FIGS. 37-38 illustrate cross sections Y₁, and Y₂, respectively, of the plurality of nanodevices after the formation of a ninth trench, backside ILD (BILD) layer deposition, and CMP, in accordance with the embodiment of the present invention.

FIGS. 39-40 illustrate cross sections Y₁, and Y₂, respectively, of the plurality of nanodevices after the formation of a backside power rail (BPR) and a backside power delivery network (BSPDN), in accordance with the embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

References in the specification to “one embodiment,” “an embodiment,” “an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “formed on,” or “formed atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be a direct or indirect positional relationship. As an example of an indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes which are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.
Clause 1. A semiconductor device includes a first nanodevice including a plurality of first transistors, where the first nanodevice includes a first source/drain contact having a first bulge towards a backside of the first source/drain contact, and a second nanodevice including a plurality of second transistors, where the second nanodevice is located adjacent to and parallel to the first nanodevice along an x-axis. The first bulge is located between the first nanodevice and the second nanodevice. A backside via extends downwards from a backside of the first nanodevice and the second nanodevice to connect to a backside of the first bulge.
Clause 2. The semiconductor device of clause 1, where the first bulge may extend laterally along a y-axis from an inner sidewall of the first source/drain contact.
Clause 3. The semiconductor device of any of the preceding clauses, where the first source/drain contact having the first bulge may have substantially an L-shaped profile through a cross section of a source/drain region.
Clause 4. The semiconductor device of any of the preceding clauses, where the first bulge may have substantially an elliptical shape through the cross section of the source/drain region.
Clause 5. The semiconductor device of any of the preceding clauses, where the first bulge may extend a first height perpendicular to the y-axis, where the first source/drain contact may extend a second height perpendicular to the y-axis, and where the second height may be greater than the first height.
Clause 6. The semiconductor device of any of the preceding clauses, where the backside of the first source/drain contact and a backside of the first bulge may together extend a first width along the y-axis, where a frontside of the first source/drain contact may extend a second width along the y-axis, and where the first width may be greater than the second width.
Clause 7. The semiconductor device of any of the preceding clauses, where the semiconductor device may further comprise a first backside dielectric liner extending along a first sidewall of the backside via, where the first backside dielectric liner may extend a third height perpendicular to the y-axis. A second backside dielectric liner may extend along a second sidewall of the backside via, where the second backside dielectric liner may extend a fourth height perpendicular to the y-axis, where the fourth height may be greater than the third height.
Clause 8. A semiconductor device includes a first nanodevice including a plurality of first transistors, where the first nanodevice includes a first source/drain contact having a first bulge towards a backside of the first source/drain contact, and a second nanodevice including a plurality of second transistors, where the second nanodevice is located adjacent to and parallel to the first nanodevice along an x-axis. The second nanodevice includes a second source/drain contact having a second bulge towards a backside of the second source/drain contact. The first bulge is located between the first nanodevice and the second nanodevice. A backside via extends downwards from a backside of the first nanodevice and the second nanodevice to connect to a backside of the first bulge.
Clause 9. The semiconductor device of any of the preceding clauses, where the first source/drain contact having the first bulge and the second source/drain contact having the second bulge may be oriented in substantially a same direction.
Clause 10. The semiconductor device of any of the preceding clauses, where the first bulge may extend laterally along a y-axis from an inner sidewall of the first source/drain contact, and where the second bulge may extend laterally along the y-axis from an outer sidewall of the second source/drain contact.
Clause 11. The semiconductor device of any of the preceding clauses, where the first source/drain contact having the first bulge and the second source/drain contact having the second bulge may have substantially an L-shaped profile through a cross section of a source/drain region.
Clause 12. The semiconductor device of any of the preceding clauses, where the first bulge and the second bulge may have substantially an elliptical shape through the cross section of the source/drain region.
Clause 13. The semiconductor device of any of the preceding clauses, where the first bulge and the second bulge may each extend a first height perpendicular to the y-axis, where the first source/drain contact and the second source/drain contact may each extend a second height perpendicular to the y-axis, and where the second height may be greater than the first height.
Clause 14. The semiconductor device of any of the preceding clauses, where the backside of the first source/drain contact and a backside of the second source/drain contact may together extend a first width along the y-axis, where the backside of the second source/drain contact and a backside of the second bulge may together extend the first width along the y-axis, where a frontside of the first source/drain contact and a frontside of the second source/drain contact may each extend a second width along the y-axis, and where the first width is greater than the second width.
Clause 15. A semiconductor device includes a first nanodevice including a plurality of first transistors, where the first nanodevice includes a first source/drain contact having a first bulge towards a backside of the first source/drain contact, and a second nanodevice including a plurality of second transistors, where the second nanodevice is located adjacent to and parallel to the first nanodevice along an x-axis. The second nanodevice includes a second source/drain contact having a second bulge towards a backside of the second source/drain contact. The first bulge is located between the first nanodevice and the second nanodevice. A backside via extends downwards from a backside of the first nanodevice and the second nanodevice to connect to a backside of the first bulge. A backside power rail connects to a backside of the backside of the backside via.
Clause 16. The semiconductor device of any of the preceding clauses, where the first source/drain contact having the first bulge and the second source/drain contact having the second bulge may be oriented in substantially a same direction.
Clause 17. The semiconductor device of any of the preceding clauses, where the first bulge may extend laterally along a y-axis from an inner sidewall of the first source/drain contact, and where the second bulge may extend laterally along the y-axis from an outer sidewall of the second source/drain contact.
Clause 18. The semiconductor device of any of the preceding clauses, where the first source/drain contact having the first bulge and the second source/drain contact having the second bulge may have substantially an L-shaped profile through a cross section of a source/drain region.
Clause 19. The semiconductor device of any of the preceding clauses, where the first bulge and the second bulge may each extend a first height perpendicular to the y-axis, where the first source/drain contact and the second source/drain contact may each extend a second height perpendicular to the y-axis, and where the second height may be greater than the first height.
Clause 20. The semiconductor device of any of the preceding clauses, where the semiconductor device may further comprise a source/drain connected to the backside of the first source/drain contact, where the backside power rail may connect to the source/drain by the backside via and the first bulge.

When a via to the backside power rail (VBPR) extends downwards from a frontside contact the via may be located between two active regions on a nanodevice. The downwards extending VBPR is connected to a component, for example, a backside power rail. As the surface area of the frontside contact is extended to accommodate the VBPR, there is a high risk of a tip-to-tip short between the frontside contact having the VBPR and an adjacent frontside contact during patterning.

By forming a via from a backside of the nanodevice, the risk of the tip-to-tip short may be greatly reduced. Additionally, the smaller surface area of the frontside contact may simplify patterning. The present invention does not require that all advantages need to be incorporated into every embodiment of the invention.

The present invention is directed to forming a backside via in a space between a plurality of nanodevices (e.g., PFET and/or NFET transistors) such that the backside via connects a source/drain contact to a backside power rail. The backside via is formed through a multistage processing, where the first stage forms a first trench and a second trench by etching a portion of an interlayer dielectric. The second stage forms first frontside dielectric liners and second frontside dielectric liners along sidewalls of the first trench and the second trench. The third stage forms a third trench and a fourth trench by etching a portion of the interlayer dielectric. The fourth stage fills the first trench, the second trench, the third trench, and the fourth trench with a conductive metal to form a first source/drain contact having a first bulge and a second source/drain contact having a second bulge. The fifth stage forms a fifth trench, a sixth trench, and a seventh trench by etching a portion of an underlying substrate liner, a shallow trench isolation region, a gate, and the interlayer dielectric. The sixth stage forms backside dielectric liners along sidewalls of the fifth trench, sixth trench, and seventh trench. The seventh stage forms a backside dielectric fill along sidewalls of the backside dielectric liners. The eighth stage forms an eighth trench by etching a portion of the backside dielectric fill. The ninth stage fills the eighth trench with the conductive metal to form the backside via connected to the first bulge.

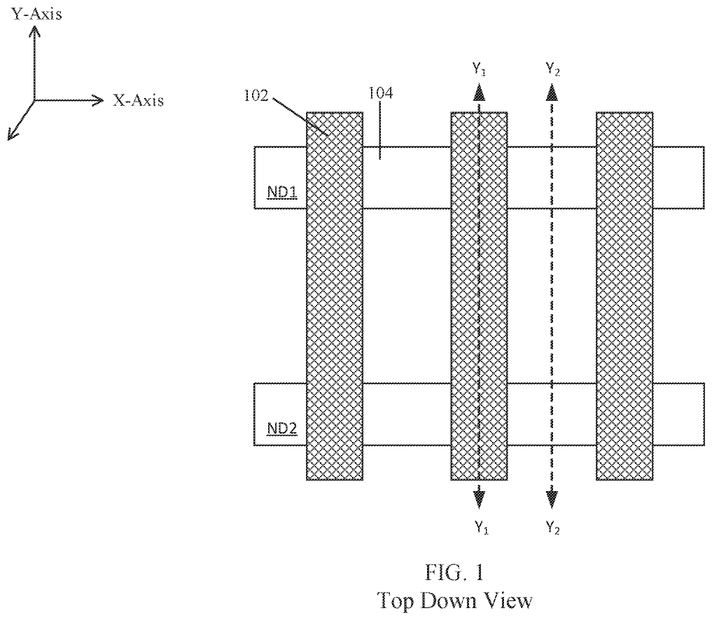

FIG. 1 illustrates a top-down view of a plurality of nanodevices ND1, ND2, in accordance with the embodiment of the present invention. The adjacent and parallel devices along an x-axis include a first nanodevice ND1 including a plurality of first transistors and a second nanodevice ND2 including a plurality of second transistors. Cross-section Y₁ is a cross section parallel to the gates in the gate region 102 across the plurality of nanodevices ND1, ND2. Cross-section Y₂ is a cross section parallel to the gates in the source/drain region 104 across the plurality of nanodevices ND1, ND2. It may be appreciated that the embodiment of the present invention is not limited to nanodevices ND1, ND2 and that other devices including, but not limited to, nanosheet transistors, FinFET, nanowire, and a planar device may also be used.

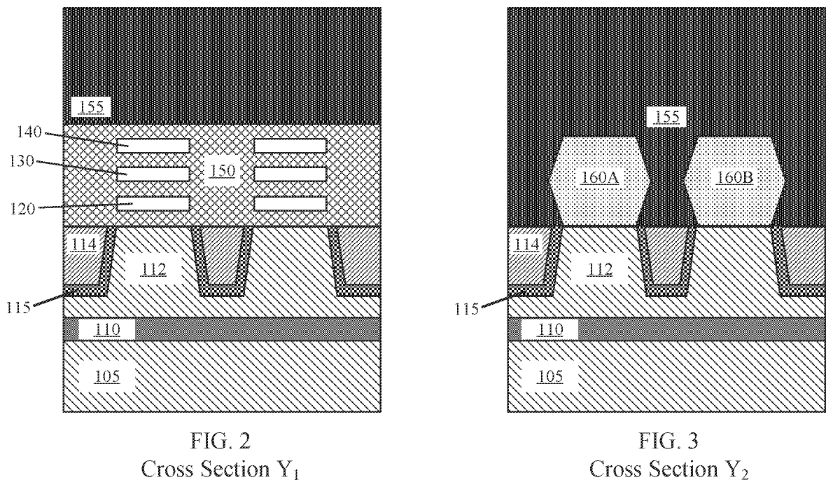

FIGS. 2-3 illustrate cross sections Y₁, and Y₂, respectively, of the plurality of nanodevices ND1, ND2 after interlayer dielectric (ILD) 155 deposition, nanosheet 120, 130, 140 formation, shallow trench isolation (STI) region 114 formation, gate 150 formation, source/drain 160A, 160B formation, etch stop layer 110 formation, underlying substrate liner 115 formation, and CMP, in accordance with the embodiment of the present invention. The plurality of nanodevices ND1, ND2 include a substrate 105, an etch stop layer 110, an underlying substrate layer 112, an STI region 114, an underlying substrate liner 115, a first nanosheet 120, a second nanosheet 130, and a third nanosheet 140. The substrate 105 and the etch stop layer 110 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 and the etch stop layer 110 may be doped, undoped or contain doped regions and undoped regions therein.

The first sacrificial layer (not shown) is formed directly atop the underlying substrate layer 112. The first nanosheet 120 is formed directly atop the first sacrificial layer (not shown). The second sacrificial layer (not shown) is formed directly atop the first nanosheet 120. The second nanosheet 130 is formed directly atop the second sacrificial layer (not shown). The third sacrificial layer (not shown) is formed directly atop the second nanosheet 130. The third nanosheet 140 is formed directly atop the third sacrificial layer (not shown). The first sacrificial layer (not shown), the second sacrificial layer (not shown), and the third sacrificial layer (not shown) are hereinafter referred to as the plurality of sacrificial layers (not shown). In addition, the first nanosheet 120, the second nanosheet 130, and the third nanosheet 140 are hereinafter referred to as the plurality of nanosheets 120, 130, 140. The plurality of sacrificial layers (not shown) may be comprised of, for example, SiGe, where Ge is about 35%. The plurality of nanosheets 120, 130, 140 may be comprised of, for example, Si. The number of nanosheets and the number of sacrificial layers described above are not intended to be limiting, and it may be appreciated that in the embodiment of the present invention the number of nanosheets and the number of sacrificial layers may vary. After formation of the plurality of nanosheets 120, 130, 140 and the plurality of sacrificial layers (not shown), together the nanosheet stack, the nanosheet stack (comprising alternative Si and SiGe layers) may be further patterned using conventional lithography and etching processes. After nanosheet stack formation and patterning, the STI region 114 and the underlying substrate liner 115 is formed by dielectric filling, CMP, and dielectric recess.

Then, the first source/drain 160A and the second source/drain 160B are epitaxially grown over exposed sidewalls of the plurality of nanosheets 120, 130, 140, followed by ILD 155 deposition and CMP to remove a dummy gate hard mask (not shown). Then, the sacrificial layers (not shown) are removed, followed by gate 150 formation. The first source/drain 160A and the second source/drain 160B are formed directly atop the underlying substrate layer 112.

The first source/drain 160A and the second source/drain 160B can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

In FIG. 2, the ILD 155 is formed directly atop the gate 150. In FIG. 3, the ILD 155 is formed directly atop the first source/drain 160A, the second source/drain 160B, the underlying substrate liner 115, and the STI region 114.

In FIG. 2, a gate material is deposited in the space created by the removal of the plurality of sacrificial layers (not shown) and directly atop the third nanosheet 140, the STI region 114, and the underlying substrate liner 115 to form a replacement gate (i.e., the gate 150). The gate 150 can be comprised of, for example, a gate dielectric liner, such as a high-k dielectric like HfO2, ZrO2, HfLaOx, etc., and work function layers, such as TiN, TiAlC, TiC, etc., and conductive metal fills, like W.

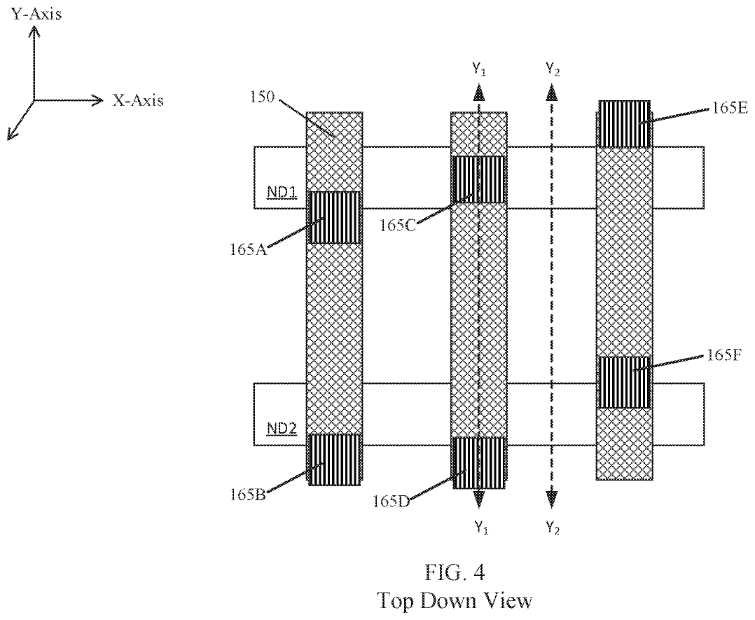

FIG. 4 illustrates a top-down view of the plurality of nanodevices ND1, ND2 after the formation of a plurality of gate contacts 165A, 165B, 165C, 165D, 165E, 165F, in accordance with the embodiment of the present invention. FIG. 4 is meant to illustrate the location of the plurality of gate contacts 165A, 165B, 165C, 165D, 165E, 165F with respect to the plurality of nanodevices ND1, ND2. A plurality of trenches (not shown) formed during middle-of-line (MOL) patterning are filled with a conductive metal (e.g., including a silicide liner, such as Ni, Ti, NiPt, an adhesion metal liner, such as TiN and conductive metal fill, such as W, Co, or Ru) to form the plurality of gate contacts 165A, 165B, 165C, 165D, 165E, 165F.

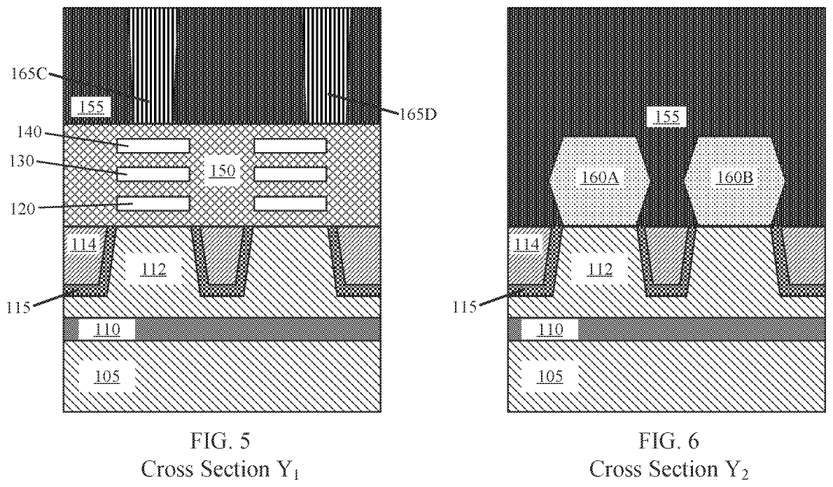

FIGS. 5-6 illustrate cross sections Y₁, and Y₂, respectively, of the plurality of nanodevices ND1, ND2 after the formation of the plurality of gate contacts 165A, 165B, 165C, 165D, 165E, 165F, in accordance with the embodiment of the present invention. In FIG. 5, the third gate contact 165C and the fourth gate contact 165D are located directly atop the gate 150.

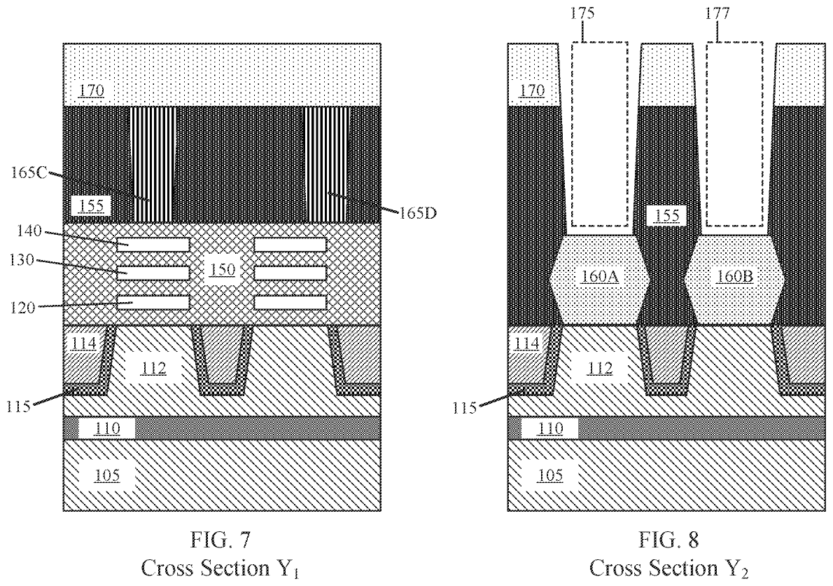

FIGS. 7-8 illustrate cross sections Y₁, and Y₂, respectively, of the plurality of nanodevices ND1, ND2 after the formation of a lithography mask layer 170, a first trench 175, and a second trench 177, in accordance with the embodiment of the present invention. The lithography mask layer 170 may be, for example, an organic planarization layer (OPL). In FIG. 7, the lithography mask layer 170 is deposited directly atop the ILD 155, the third gate contact 165C, and the fourth gate contact 165D. In FIG. 8, the lithography mask layer 170 is deposited and then patterned directly atop the ILD 155 to expose a portion of the underlying ILD 155. The exposed portion of the ILD 155 is etched by, for example, RIE to form the first trench 175 and the second trench 177. A bottom surface of the first trench 175 and the second trench 177 exposes a top surface of the first source/drain 160A and the second source/drain 160B, respectively. In FIGS. 7-8, the lithography mask layer 170 is formed by depositing, for example, an OPL material in a spin-on coating process.

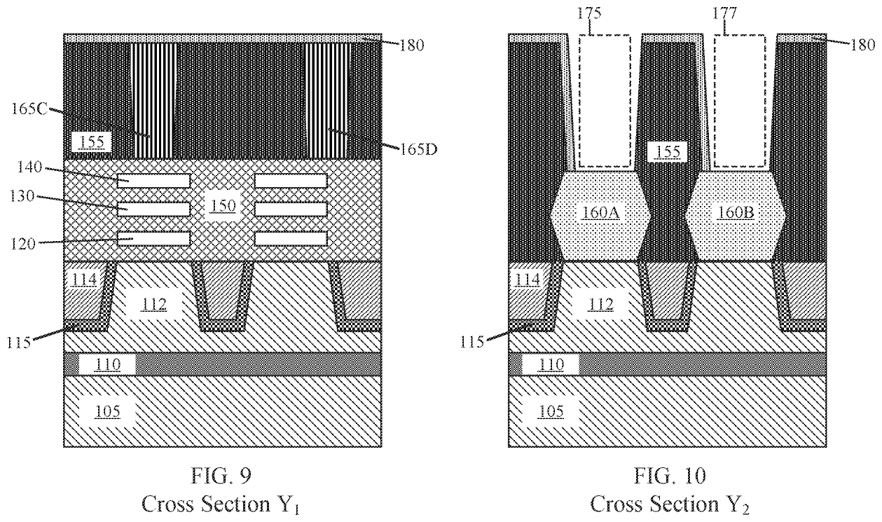

FIGS. 9-10 illustrate cross sections Y₁, and Y₂, respectively, of the plurality of nanodevices ND1, ND2 after the formation of a plurality of first frontside dielectric liners 180, in accordance with the embodiment of the present invention. In FIG. 9, a liner material is deposited directly atop the ILD 155, the third gate contact 165C, and the fourth gate contact 165D to form the plurality of first frontside dielectric liners 180. In FIG. 10, the liner material is deposited directly atop the ILD 155, and in the first trench 175 and the second trench 177 by an angled deposition technique to form the plurality of first frontside dielectric liners 180 located on an outer sidewall of the first trench 175 and an inner sidewall of the second trench 177. In FIGS. 9 and 10, the liner material may be comprised of, for example, SiN, SiBCN, SiOCN, SiOC, or SiC.

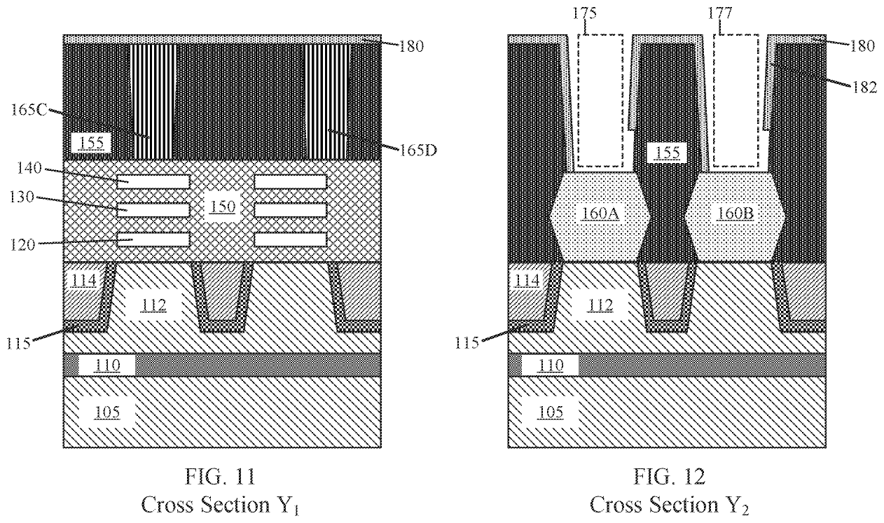

FIGS. 11-12 illustrate cross sections Y₁, and Y₂, respectively, of the plurality of nanodevices ND1, ND2 after the formation of a plurality of second frontside dielectric liners 182, in accordance with the embodiment of the present invention. The same liner material described above is deposited in the first trench 175 and the second trench 177 by the angled deposition technique to form the plurality of second frontside dielectric liners 182 located on an inner sidewall of the first trench 175 and an outer sidewall of the second trench 177.

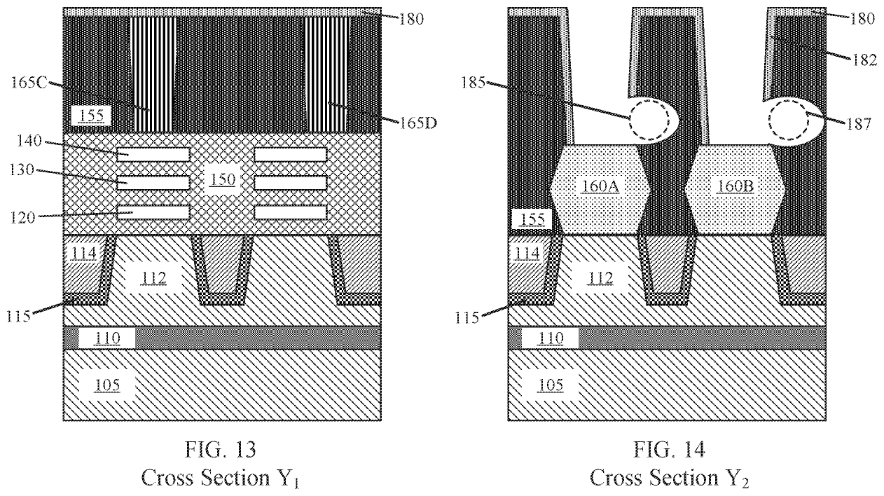

FIGS. 13-14 illustrate cross sections Y₁, and Y₂, respectively, of the plurality of nanodevices ND1, ND2 after the formation of a third trench 185 and a fourth trench 187, in accordance with the embodiment of the present invention. A portion of the ILD 155 is etched isotopically by, for example, RIE to form the third trench 185 and the fourth trench 187. The third trench 185 and the fourth trench 187 are connected to the first trench 175 (FIG. 12) and the second trench 177 (FIG. 12), respectively.

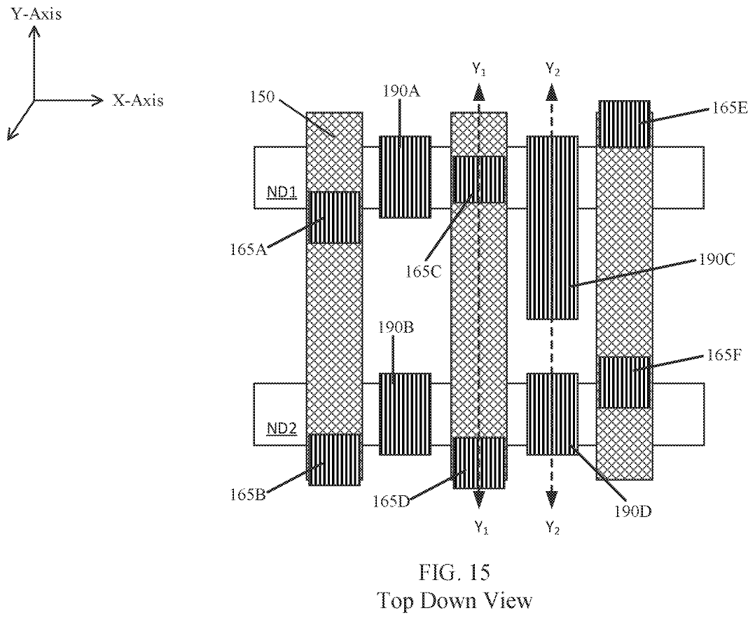

FIG. 15 illustrates a top-down view of the plurality of nanodevices ND1, ND2 after the formation of a plurality of source/drain contacts 190A, 190B, 190C, 190D, in accordance with the embodiment of the present invention. FIG. 15 is meant to illustrate the location of the plurality of source/drain contacts 190A, 190B, 190C, 190D with respect to the plurality of nanodevices ND1, ND2. The first trench 175 (FIG. 12), the second trench 177 (FIG. 12), the third trench 185 (FIG. 14), and the fourth trench 187 (FIG. 14) are filled with the conductive metal (e.g., including a silicide liner, such as Ni, Ti, NiPt, an adhesion metal liner, such as TiN and conductive metal fill, such as W, Co, or Ru) to form the plurality of source/drain contacts 190A, 190B, 190C, 190D.

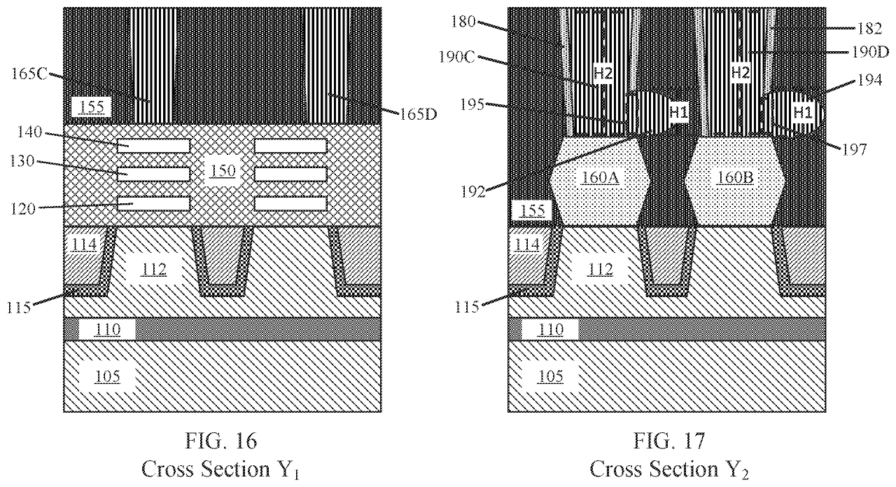

FIGS. 16-17 illustrate cross sections Y₁, and Y₂, respectively, of the plurality of nanodevices ND1, ND2 after the formation of the plurality of source/drain contacts 190A (FIG. 15), 190B (FIG. 15), 190C, 190D, in accordance with the embodiment of the present invention. The third source/drain contact 190C (i.e., the first source/drain contact in the claims) is located directly atop the first source/drain 160A and has a first bulge 192 towards a backside of the third source/drain contact 190C. The first bulge 192 is located between the first nanodevice ND1 and the second nanodevice ND2. The fourth source/drain contact 190D (i.e., the second source/drain contact in the claims) is located directly atop the second source/drain 160B and has a second bulge 194 towards a backside of the fourth source/drain contact 190D. Dashed box 195 and dashed box 197 illustrate a first source/drain contact-bulge link and a second source/drain contact-bulge link, respectively, connecting the third source/drain contact 190C to the first bulge 192 and the fourth source/drain contact 190D to the second bulge 194.

The first bulge 192 extends laterally along the y-axis from an inner sidewall of the third source/drain contact 190C. The second bulge 194 extends laterally along the y-axis from an outer sidewall of the fourth source/drain contact 190D. The third source/drain contact 190C having the first bulge 192 and the fourth source/drain contact 190D having the second bulge 194 are oriented in substantially the same direction. The third source/drain contact 190C having the first bulge 192 and the fourth source/drain contact 190D having the second bulge 194 have substantially an L-shaped profile through a cross section of a source/drain region 104 (FIG. 1). The first bulge 192 and the second bulge 194 have substantially an elliptical shape through the cross section of the source/drain region 104 (FIG. 1).

The first bulge 192 and the second bulge 194 each extend a first height H1 perpendicular to the y-axis. The third source/drain contact 190C and the fourth source/drain contact 190D each extend a second height H2 perpendicular to the y-axis. The second height H2 is greater than the first height H1.

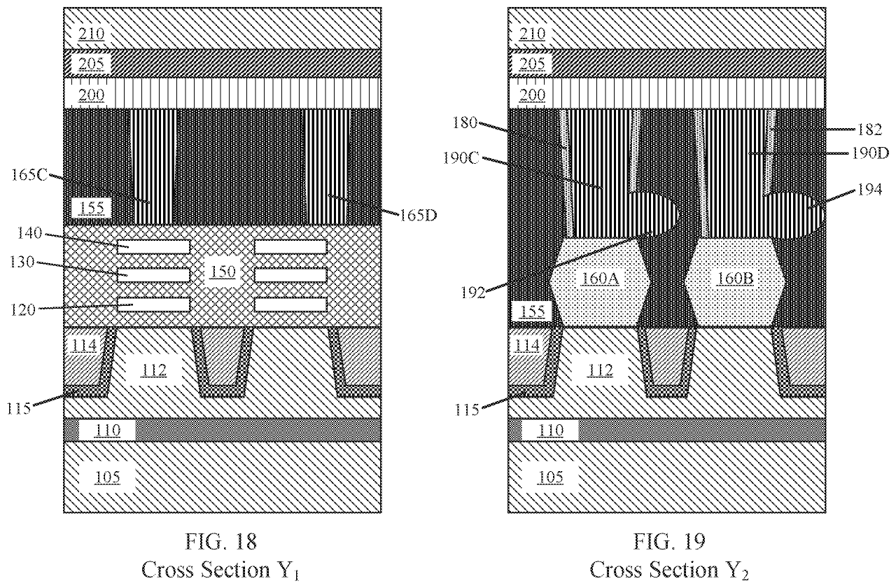

FIGS. 18-19 illustrate cross sections Y₁, and Y₂, respectively, of the plurality of nanodevices ND1, ND2 after the formation of a back-end-of-line (BEOL) layer 200, a bonding oxide layer 205, and bonding to a carrier wafer 210, in accordance with the embodiment of the present invention. The BEOL layer 200 may contain multiple metal layers and vias in between. In FIG. 18, the BEOL layer 200 is formed directly atop the ILD 155, the third gate contact 165C, and the fourth gate contact 165D. In FIG. 19, the BEOL layer 200 is formed directly atop the ILD 155, the plurality of first frontside dielectric liners 180, the plurality of second frontside dielectric liners 182, the third source/drain contact 190C, and the fourth source/drain contact 190D. In FIGS. 18-19, the bonding oxide layer 205 is formed directly atop the BEOL layer 200. The carrier wafer 210 is formed directly atop the bonding oxide layer 205 by bonding processes (e.g., oxide-oxide bonding).

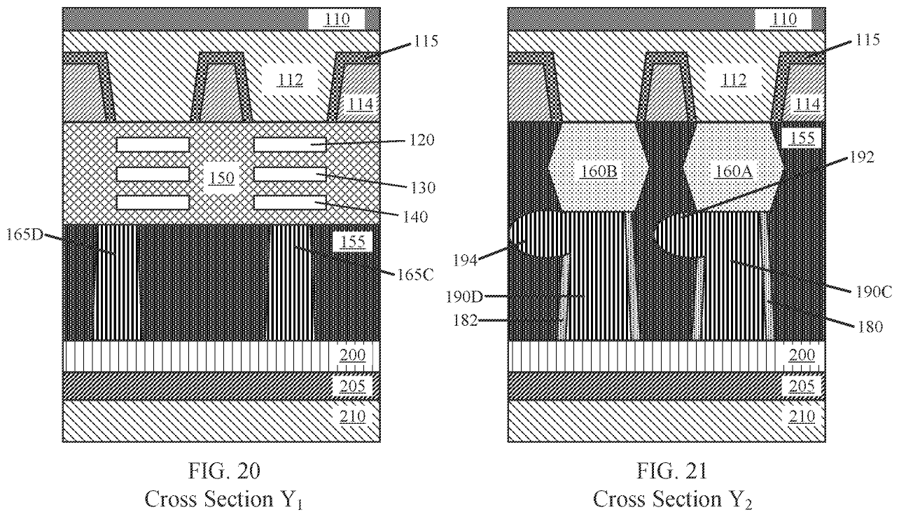

FIGS. 1-19 illustrate the processing of the frontside of the substrate 105, while FIGS. 20-40 illustrate the processing of the backside of the substrate 105. FIGS. 20-21 illustrate cross sections Y₁, and Y₂, respectively, of the plurality of nanodevices ND1, ND2 after the carrier wafer 210 is flipped and the substrate 105 is removed, in accordance with the embodiment of the present invention. The carrier wafer 210 is flipped and the carrier wafer 210 becomes a handler wafer. The substrate 105 is removed by, for example, a combination of processes such as wafer grinding, CMP, and/or selective dry/wet etch, stopping on the etch stop layer 110.

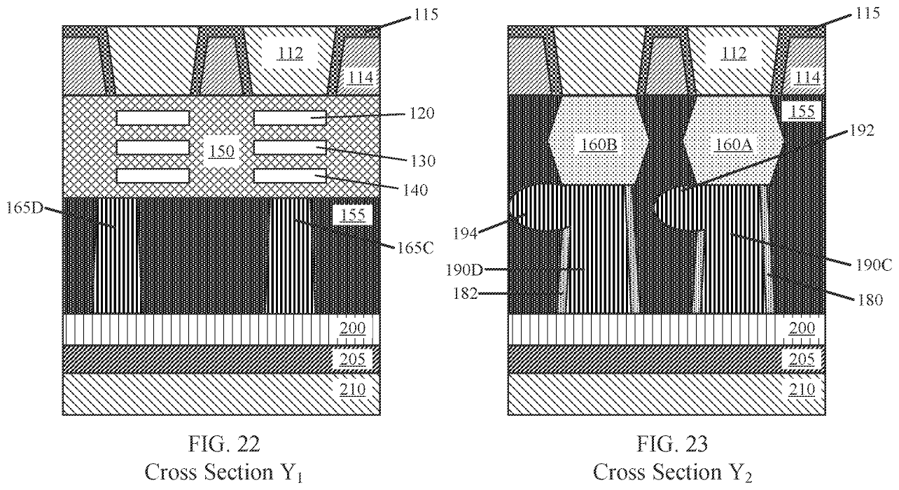

FIGS. 22-23 illustrate cross sections Y₁, and Y₂, respectively, of the plurality of nanodevices ND1, ND2 after the removal of the etch stop layer 110 and the selective recessing of the underlying substrate layer 112, in accordance with the embodiment of the present invention. The etch stop layer 110 is removed to expose the underlying substrate layer 112. A portion of the underlying substrate layer 112 is removed by, for example, a selective wet or dry etch process.

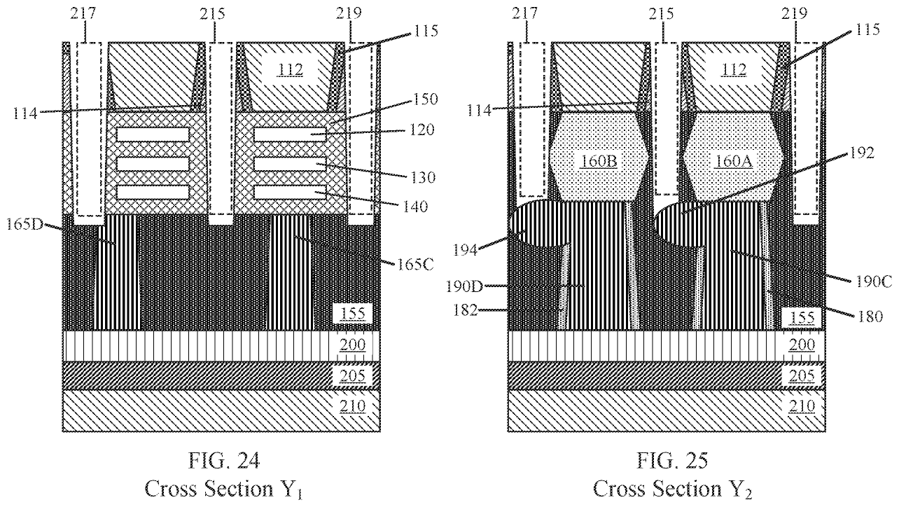

FIGS. 24-25 illustrate cross sections Y₁, and Y₂, respectively, of the plurality of nanodevices ND1, ND2 after the formation of a fifth trench 215, a sixth trench 217, and a seventh trench 219, in accordance with the embodiment of the present invention. In FIG. 24, a portion of the STI region 114, the underlying substrate liner 115, the gate 150, and the ILD 155 are etched by, for example, RIE to form the fifth trench 215. A bottom surface of the fifth trench 215 exposes a portion of a top surface of the ILD 155. In FIG. 25, a portion of the STI region 114, the underlying substrate liner 115, and the ILD 155 are etched by, for example, RIE to form the fifth trench 215. A bottom surface of the fifth trench 215 exposes a portion of a top surface of the first bulge 192. In FIG. 24, a portion of the STI region 114, the underlying substrate liner 115, the gate 150, and the fourth gate contact 165D are etched by, for example, RIE to form the sixth trench 217. A bottom surface of the sixth trench 217 exposes a portion of a top surface of the ILD 155 and the fourth gate contact 165D. In FIG. 25, a portion of the STI region 114, the underlying substrate liner 115, and the ILD 155 are etched by, for example, RIE to form the sixth trench 217. A bottom surface of the sixth trench 217 exposes a portion of a top surface of the second bulge 194. In FIG. 24, a portion of the STI region 114, the underlying substrate liner 115, the gate 150, and the ILD 155 are etched by, for example, RIE to form the seventh trench 219. In FIG. 25, a portion of the STI region 114, the underlying substrate liner 115, and the ILD 155 are etched by, for example, RIE to form the seventh trench 219. In FIGS. 24-25, a bottom surface of the seventh trench 219 exposes a portion of a top surface of the ILD 155.

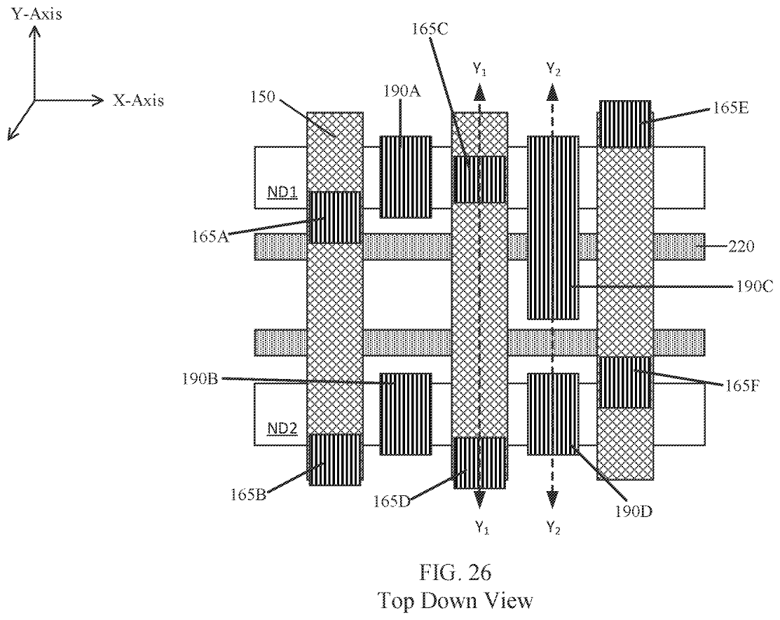

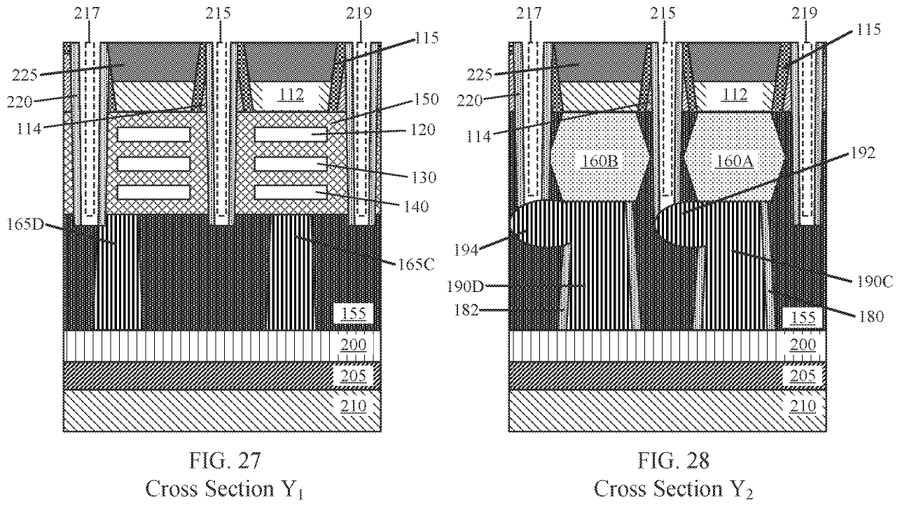

FIG. 26 illustrates a top-down view of the plurality of nanodevices ND1, ND2 after the formation of a plurality of backside dielectric liners 220 and a plurality of dielectric caps 225 (FIGS. 27-28), in accordance with the embodiment of the present invention. FIG. 26 is meant to illustrate a cut in the gate region 102 (FIG. 1) that is filled to form the plurality of backside dielectric liners 220.

FIGS. 27-28 illustrate cross sections Y₁, and Y₂, respectively, of the plurality of nanodevices ND1, ND2 after the formation of the plurality of backside dielectric liners 220 and the plurality of dielectric caps 225, in accordance with the embodiment of the present invention. The liner material is deposited in the fifth trench 215, the sixth trench 217, and the seventh trench 219 and etched back to form the plurality of backside dielectric liners 220 located on sidewalls of the fifth trench 215, the sixth trench 217, and the seventh trench 219. An additional portion of the underlying substrate layer 112 is removed by, for example, a selective wet or dry etch process. Then, a dielectric material is deposited in the space created by the removal of the additional portion of the underlying substrate layer 112 to form the plurality of dielectric caps 225 directly atop the underlying substrate layer 112.

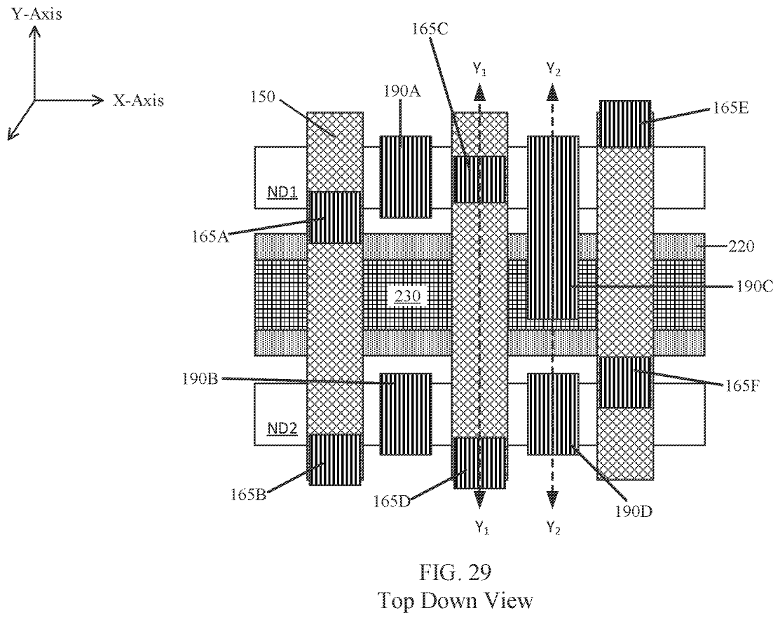

FIG. 29 illustrates a top-down view of the plurality of nanodevices ND1, ND2 after the formation of a dielectric fill 230, in accordance with the embodiment of the present invention. FIG. 29 is meant to illustrate the cut in the gate region 102 (FIG. 1) that is filled to form the dielectric fill 230.

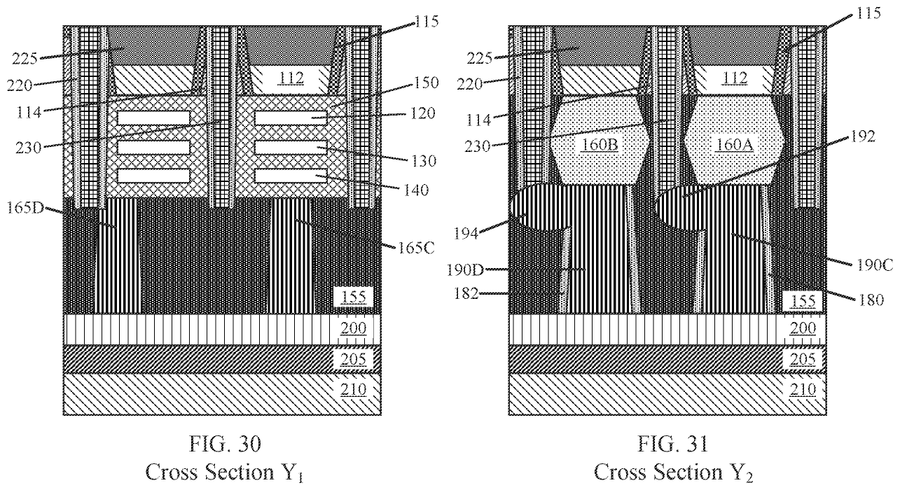

FIGS. 30-31 illustrate cross sections Y₁, and Y₂, respectively, of the plurality of nanodevices ND1, ND2 after the formation of the dielectric fill 230, in accordance with the embodiment of the present invention. A dielectric fill material is deposited in the fifth trench 215 (FIGS. 27-28), the sixth trench 217 (FIGS. 27-28), and the seventh trench 219 (FIGS. 27-28) and etched by, for example, CMP to form the dielectric fill 230 located between the plurality of backside dielectric liners 220. The dielectric fill 230 may be comprised of, for example, SiO₂.

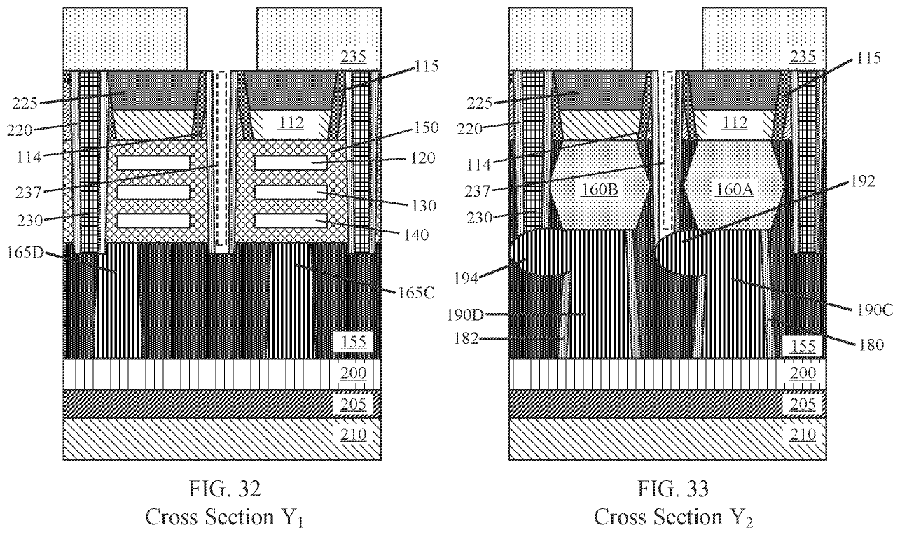

FIGS. 32-33 illustrate cross sections Y₁, and Y₂, respectively, of the plurality of nanodevices ND1, ND2 after the formation of a second lithography mask layer 235 and an eighth trench 237, in accordance with the embodiment of the present invention. The second lithography mask layer 235, for example, an organic planarization layer (OPL), is deposited and then patterned directly atop the underlying substrate liner 115, the plurality of backside dielectric liners 220, the plurality of dielectric caps 225, and the dielectric fill 230 to expose a portion of the underlying substrate liner 115, the plurality of backside dielectric liners 220, the plurality of dielectric caps 225, and the dielectric fill 230. The exposed portion of the dielectric fill 230 is etched by, for example, RIE to form the eighth trench 237. In FIG. 32, a bottom surface of the eighth trench 237 exposes a portion of a top surface of the ILD 155. In FIG. 33, a bottom surface of the eight trench 237 exposes a portion of a top surface of the first bulge 192. In FIGS. 32-33, the second lithography mask layer 235 is formed by depositing, for example, an OPL material in a spin-on coating process.

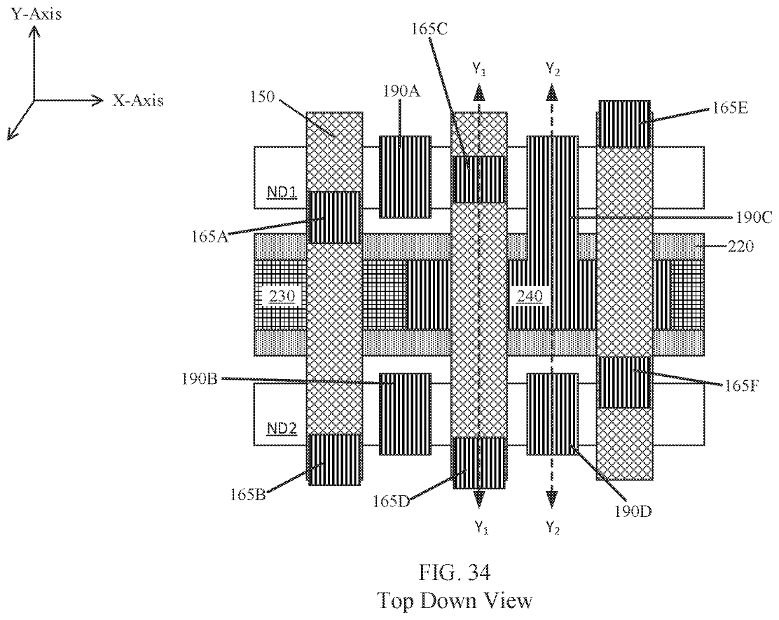

FIG. 34 illustrates a top-down view of the plurality of nanodevices ND1, ND2 after the formation of a backside via 240, in accordance with the embodiment of the present invention. FIG. 34 is meant to illustrate the connection between the backside via 240 and the third source/drain contact 190C.

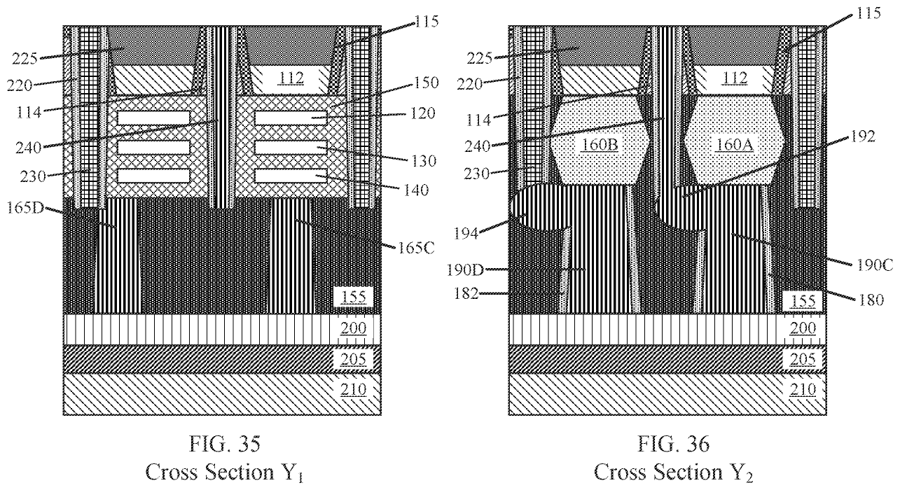

FIGS. 35-36 illustrate cross sections Y₁, and Y₂, respectively, of the plurality of nanodevices ND1, ND2 after the formation of the backside via 240, in accordance with the embodiment of the present invention. The second lithography mask layer 235 is removed. The eighth trench 237 (FIGS. 32-33) is filled with a conductive metal (e.g., including a silicide liner, such as Ni, Ti, NiPt, an adhesion metal liner, such as TiN and conductive metal fill, such as W, Co, or Ru) to form the backside via 240 extending downwards from a backside of the first nanodevice ND1 and the second nanodevice ND2 to connect to a backside of the first bulge 192.

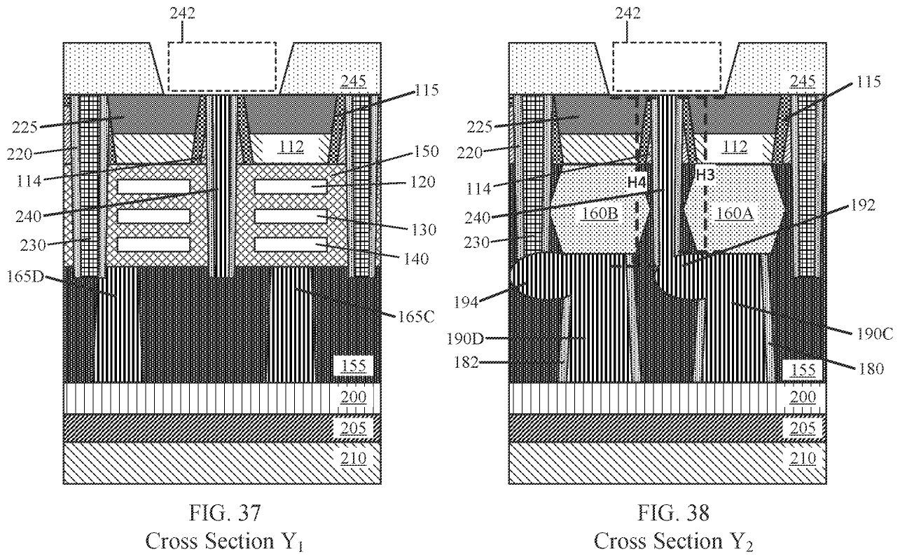

FIGS. 37-38 illustrate cross sections Y₁, and Y₂, respectively, of the plurality of nanodevices ND1, ND2 after the formation of a ninth trench 242, backside ILD (BILD) layer 245 deposition, and CMP, in accordance with the embodiment of the present invention. The BILD layer 245 may be comprised of, for example, SiC or SiOC. The BILD layer 245 is deposited directly atop the underlying substrate liner 115, the plurality of backside dielectric liners 220, the plurality of dielectric caps 225, and the dielectric fill 230. A portion of the BILD layer 245 is selectively removed by, for example, CMP to form the ninth trench 242. A bottom surface of the ninth trench 242 exposes a top surface of the backside via 240, and a portion of a top surface of the underlying substrate liner 115, the plurality of backside dielectric liners 220, and the plurality of dielectric caps 225.

In FIG. 38, a first backside dielectric liner of the plurality of backside dielectric liners 220 extends along a first sidewall of the backside via 240. The first backside dielectric liner extends a third height H3 perpendicular to the y-axis. A second backside dielectric liner of the plurality of backside dielectric liners 220 extends along a second sidewall of the backside via 240. The second backside dielectric liner extends a fourth height H4 perpendicular to the y-axis. The fourth height H4 is greater than the third height H3.

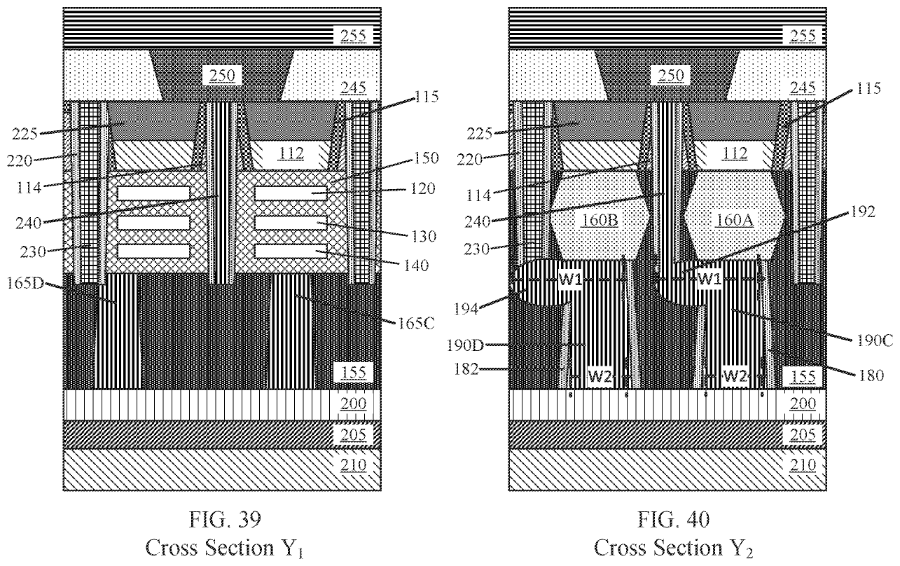

FIGS. 39-40 illustrate cross sections Y₁, and Y₂, respectively, of the plurality of nanodevices ND1, ND2 after the formation of a backside power rail (BPR) 250 and a backside power delivery network (BSPDN) 255, in accordance with the embodiment of the present invention. The ninth trench 242 is filled with a conductive metal (e.g., Cu, Co or Ru fill with adhesion liner such as TiN) to form the BPR 250 located directly atop the backside via 240, and directly atop a portion of the underlying substrate liner 115, the plurality of backside dielectric liners 220, and the plurality of dielectric caps 225. The BPR 250 connects to a backside of the backside via 240. The first source/drain 160A (i.e., the source/drain in the claims) connects to the backside of the third source/drain contact 190C. The BPR 250 connects to the first source/drain 160A by the backside via 240 and the first bulge 192. The BSPDN 255 is formed directly atop the BILD layer 245 and the BPR 250.

In FIG. 40, the backside of the third source/drain contact 190C and a backside of the first bulge 192 together extend a first width W1 along the y-axis. The backside of the fourth source/drain contact 190D and a backside of the second bulge 194 together extend the first width W1 along the y-axis. A frontside of the third source/drain contact 190C and a frontside of the fourth source/drain contact 190D each extend a second width W2 along the y-axis. The first width W1 is greater than the second width W2.

The third source/drain contact 190C has the first bulge 192 towards the backside of the third source/drain contact 190C. The fourth source/drain contact 190D has the second bulge 194 towards the backside of the fourth source/drain contact 190D. The backside via 240 extends downwards from the first nanodevice ND1 and the second nanodevice ND2 to connect to the backside of the first bulge 192. The first bulge 192 extends laterally along the y-axis from the inner sidewall of the third source/drain contact 190C. The second bulge 194 extends laterally along the y-axis from the outer sidewall of the fourth source/drain contact 190D. The third source/drain contact 190C having the first bulge 192 and the fourth source/drain contact 190D having the second bulge 194 have substantially the L-shaped profile through the cross section of the source/drain region 104 (FIG. 1).

It may be appreciated that FIGS. 1-40 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first nanodevice including a plurality of first transistors, wherein the first nanodevice includes a first source/drain contact having a first bulge towards a backside of the first source/drain contact;
a second nanodevice including a plurality of second transistors, wherein the second nanodevice is located adjacent to and parallel to the first nanodevice along an x-axis, wherein the first bulge is located between the first nanodevice and the second nanodevice; and
a backside via extending downwards from a backside of the first nanodevice and the second nanodevice to connect to a backside of the first bulge.

2. The semiconductor device of claim 1, wherein the first bulge extends laterally along a y-axis from an inner sidewall of the first source/drain contact.

3. The semiconductor device of claim 2, wherein the first source/drain contact having the first bulge has substantially an L-shaped profile through a cross section of a source/drain region.

4. The semiconductor device of claim 3, wherein the first bulge has substantially an elliptical shape through the cross section of the source/drain region.

5. The semiconductor device of claim 4, wherein the first bulge extends a first height perpendicular to the y-axis, wherein the first source/drain contact extends a second height perpendicular to the y-axis, and wherein the second height is greater than the first height.

6. The semiconductor device of claim 5, wherein the backside of the first source/drain contact and a backside of the first bulge together extend a first width along the y-axis, wherein a frontside of the first source/drain contact extends a second width along the y-axis, and wherein the first width is greater than the second width.

7. The semiconductor device of claim 6, further comprising:
a first backside dielectric liner extending along a first sidewall of the backside via, wherein the first backside dielectric liner extends a third height perpendicular to the y-axis;
a second backside dielectric liner extending along a second sidewall of the backside via, wherein the second backside dielectric liner extends a fourth height perpendicular to the y-axis, wherein the fourth height is greater than the third height.

8. A semiconductor device comprising:
a first nanodevice including a plurality of first transistors, wherein the first nanodevice includes a first source/drain contact having a first bulge towards a backside of the first source/drain contact;
a second nanodevice including a plurality of second transistors, wherein the second nanodevice is located adjacent to and parallel to the first nanodevice along an x-axis, wherein the second nanodevice includes a second source/drain contact having a second bulge towards a backside of the second source/drain contact, wherein the first bulge is located between the first nanodevice and the second nanodevice; and
a backside via extending downwards from a backside of the first nanodevice and the second nanodevice to connect to a backside of the first bulge.

9. The semiconductor device of claim 8, wherein the first source/drain contact having the first bulge and the second source/drain contact having the second bulge are oriented in substantially a same direction.

10. The semiconductor device of claim 9, wherein the first bulge extends laterally along a y-axis from an inner sidewall of the first source/drain contact, and wherein the second bulge extends laterally along the y-axis from an outer sidewall of the second source/drain contact.

11. The semiconductor device of claim 10, wherein the first source/drain contact having the first bulge and the second source/drain contact having the second bulge have substantially an L-shaped profile through a cross section of a source/drain region.

12. The semiconductor device of claim 11, wherein the first bulge and the second bulge have substantially an elliptical shape through the cross section of the source/drain region.

13. The semiconductor device of claim 12, wherein the first bulge and the second bulge each extend a first height perpendicular to the y-axis, wherein the first source/drain contact and the second source/drain contact each extend a second height perpendicular to the y-axis, and wherein the second height is greater than the first height.

14. The semiconductor device of claim 13, wherein the backside of the first source/drain contact and a backside of the first bulge together extend a first width along the y-axis, wherein the backside of the second source/drain contact and a backside of the second bulge together extend the first width along the y-axis, wherein a frontside of the first source/drain contact and a frontside of the second source/drain contact each extend a second width along the y-axis, and wherein the first width is greater than the second width.

15. A semiconductor device comprising:
a first nanodevice including a plurality of first transistors, wherein the first nanodevice includes a first source/drain contact having a first bulge towards a backside of the first source/drain contact;
a second nanodevice including a plurality of second transistors, wherein the second nanodevice is located adjacent to and parallel to the first nanodevice along an x-axis, wherein the second nanodevice includes a second source/drain contact having a second bulge towards a backside of the second source/drain contact, wherein the first bulge is located between the first nanodevice and the second nanodevice;
a backside via extending downwards from a backside of the first nanodevice and the second nanodevice to connect to a backside of the first bulge; and
a backside power rail connected to a backside of the backside via.

16. The semiconductor device of claim 15, wherein the first source/drain contact having the first bulge and the second source/drain contact having the second bulge are oriented in substantially a same direction.

17. The semiconductor device of claim 16, wherein the first bulge extends laterally along a y-axis from an inner sidewall of the first source/drain contact, and wherein the second bulge extends laterally along the y-axis from an outer sidewall of the second source/drain contact.

18. The semiconductor device of claim 17, wherein the first source/drain contact having the first bulge and the second source/drain contact having the second bulge have substantially an L-shaped profile through a cross section of a source/drain region.

19. The semiconductor device of claim 18, wherein the first bulge and the second bulge each extend a first height perpendicular to the y-axis, wherein the first source/drain contact and the second source/drain contact each extend a second height perpendicular to the y-axis, and wherein the second height is greater than the first height.

20. The semiconductor device of claim 19, further comprising:
a source/drain connected to the backside of the first source/drain contact, wherein the backside power rail connects to the source/drain by the backside via and the first bulge.
